(19) United States
(12) Patent Application Publication
(10) Pub. No.: US 2020/0106035 A1
(43) Pub. Date: Apr. 2, 2020

(54) METHOD OF MANUFACTURING AN ORGANIC PHOTODETECTOR

(71) Applicant: Sumitomo Chemical Company Limited, Tokyo (JP)

(72) Inventors: Jonathan Huggins, Cambridge (GB); Jeffrey Gray, Bromley (GB)

(73) Assignee: Sumitomo Chemical Company Limited, Tokyo (JP)

(21) Appl. No.: 16/571,026

(22) Filed: Sep. 13, 2019

(30) Foreign Application Priority Data
Sep. 28, 2018 (GB) 1815881.6

(51) Int. Cl. H01L 51/42; H01L 51/00

(52) U.S. Cl. CPC H01L 51/4253; H01L 51/0037; H01L 51/0026

(57) ABSTRACT

A method of manufacturing an organic photodetector is provided. The organic photodetector includes a bulk heterojunction layer 3 between a first electrode 2 and a second electrode 4, wherein the bulk heterojunction layer extends beyond an active photodetector area defined by the overlap area of the first and second electrodes. The second electrode may be a discontinuous electrode defining, with the first electrode, a plurality photodetector elements. In formation of the organic photodetector, the bulk heterojunction layer is heated. Upon heating, a non-polymeric component 3′a of the bulk heterojunction outside the active photodetector areas may migrate into an encapsulation layer 5. The heating may improve resolution of the photodetector.

### RELATED APPLICATIONS

This application claims foreign priority benefits under 35 U.S.C. § 119(a)-(d) or 35 U.S.C. § 365(b) of British application number 1815881.6, filed Sep. 28, 2018, the entirety of which is incorporated herein.

### BACKGROUND

This disclosure relates to a method of manufacturing organic photodetectors.

There is interest in the development of organic photosensitive electronic devices as alternatives to inorganic photoelectronic devices because they provide high flexibility and may be manufactured and processed at relatively low costs by using low temperature vacuum deposition or solution processing techniques.

Organic photovoltaic devices (OPVs) and organic photodetectors (OPDs) are examples of organic photosensitive electronic devices. Such an organic photosensitive electronic device may include as a bulk heterojunction layer a p-n junction of a donor/acceptor blend which enables the device to convert incident radiation into electrical current.

Examples of p-type (electron donor) materials are conjugated polymers, and fullerene and fullerene derivatives (e.g. C₆₀PCBM and C₇₀PCBM) are known n-type (electron acceptor) materials (see e.g. EP 1 447 860 Al and US 2012/205596).

US 2017/0365735 describes a semiconductor device that converts incoming light into an electrical current.

Cravino et al., “Characterization of Organic Solar Cells: the Importance of Device Layout”, November 2007, Volume 17, Issue 18, 3906-3910 describes adjustable parameters such as area and design that can affect the determination of the efficiency of donor-acceptor organic solar cells.

Dhritiman Gupta et al., “Area dependent efficiency of organic solar cells”, 2008, 93, 163301 describes the manner in which efficiency scales in polymer solar cells by studying these devices as a function of electrode area and incident beam size.

### SUMMARY

The present inventors have found that lateral conductivity of a bulk heterojunction layer may limit the resolution of a photodetector. For example, in a photodetector array comprising a plurality of photodetector elements, charge collection in areas of the bulk heterojunction layer where it extends between photodetector elements can reduce the resolution of the photodetector. Surprisingly, the present inventors have found that the mobility of a charge carrier in a bulk heterojunction layer may be reduced outside active areas of the photodetector elements by heating the organic photodetector device, which may give an increase in resolution.

In some embodiments of the present disclosure, a method of manufacturing an organic photodetector is provided. The organic photodetector includes a substrate, a first electrode supported on the substrate, a second electrode and a bulk heterojunction layer containing an organic electron acceptor and an organic electron donor between the first and second electrodes. An encapsulation layer is in direct contact with the bulk heterojunction layer.

The organic photodetector may have one or more organic photodetector elements. Each organic photodetector element has an active area defined by an overlap area of the first and second electrodes. The bulk heterojunction layer is a layer extending across the active area and outside of the active area. At least one of the organic electron acceptor and the organic electron donor is non-polymeric. The bulk heterojunction layer is heated. The heating may result in migration of the non-polymeric electron acceptor and/or non-polymeric electron donor into the encapsulation layer, resulting in depletion of the non-polymeric electron acceptor and/or non-polymeric electron donor in the bulk heterojunction layer.

In some embodiments, there is provided an organic photodetector manufactured according to the method.

In some embodiments, there is provided an organic photodetector, wherein the concentration of at least one of the organic electron donor and the organic electron acceptor in the bulk heterojunction layer is lower in an area outside of an active area than in the active area.

In some embodiments, there is provided a sensor including an organic photodetector and at least one light source.

### BRIEF DESCRIPTION OF THE DRAWINGS

The disclosed technology and accompanying figures describe some implementations of the disclosed technology.

FIG. 1 is a schematic illustration of a method according to some embodiments wherein the first electrode is a discontinuous electrode comprising at least two discrete first electrode areas spaced apart from one another.

FIG. 2 is a schematic illustration of the method according to some embodiments wherein the first electrode is a continuous layer.

FIG. 3 shows a side of view of an OPD according to some embodiments.

FIG. 4 shows a side view of an OPD according to some embodiments.

FIG. 5 is a photograph of a surface of a metal foil layer which was delaminated with an encapsulant layer of an OPD according to some embodiments following heating of the OPD.

The drawings are not drawn to scale and have various viewpoints and perspectives. The drawings are some implementations and examples. Additionally, some components and/or operations may be separated into different blocks or combined into a single block for the purposes of discussion of some of the embodiments of the disclosed technology. Moreover, while the technology is amenable to various modifications and alternative forms, specific embodiments have been shown by way of example in the drawings and are described in detail below. The intention, however, is not to limit the technology to the particular implementations described. On the contrary, the technology is intended to cover all modifications, equivalents, and alternatives falling within the scope of the technology as defined by the appended claims.

### DETAILED DESCRIPTION

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” As used herein, the terms “connected,” “coupled,” or any variant thereof means any connection or coupling, either direct or indirect, between two or more elements; the coupling or connection between the elements can be physical, logical, electromagnetic, or a combination thereof. Additionally, the words “herein,” “above,” “below,” and words of similar import, when used in this application, refer to this application as a whole and not to any particular portions of this application. Where the context permits, words in the Detailed Description using the singular or plural number may also include the plural or singular number respectively. The word “or,” in reference to a list of two or more items, covers all of the following interpretations of the word: any of the items in the list, all of the items in the list, and any combination of the items in the list.

The teachings of the technology provided herein can be applied to other systems, not necessarily the system described below. The elements and acts of the various examples described below can be combined to provide further implementations of the technology. Some alternative implementations of the technology may include not only additional elements to those implementations noted below, but also may include fewer elements.

These and other changes can be made to the technology in light of the following detailed description. While the description describes certain examples of the technology, and describes the best mode contemplated, no matter how detailed the description appears, the technology can be practiced in many ways. Details of the system may vary considerably in its specific implementation, while still being encompassed by the technology disclosed herein. As noted above, particular terminology used when describing certain features or aspects of the technology should not be taken to imply that the terminology is being redefined herein to be restricted to any specific characteristics, features, or aspects of the technology with which that terminology is associated. In general, the terms used in the following claims should not be construed to limit the technology to the specific examples disclosed in the specification, unless the Detailed Description section explicitly defines such terms. Accordingly, the actual scope of the technology encompasses not only the disclosed examples, but also all equivalent ways of practicing or implementing the technology under the claims.

To reduce the number of claims, certain aspects of the technology are presented below in certain claim forms, but the applicant contemplates the various aspects of the technology in any number of claim forms.

In the following description, for the purposes of explanation, numerous specific details are set forth in order to provide a thorough understanding of implementations of the disclosed technology. It will be apparent, however, to one skilled in the art that embodiments of the disclosed technology may be practiced without some of these specific details.

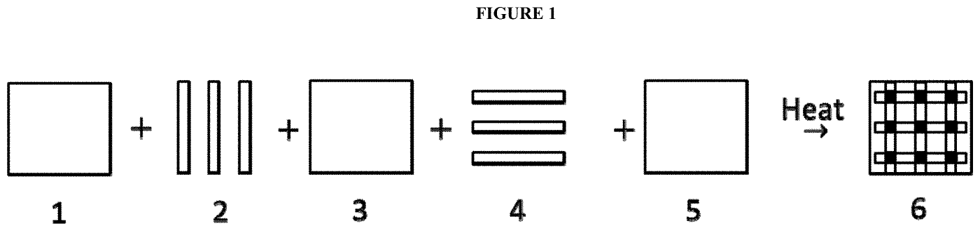

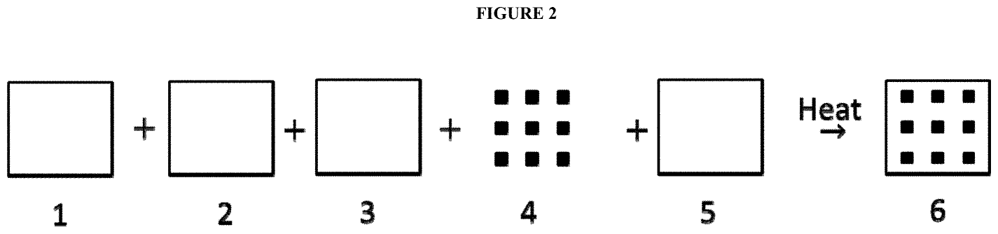

FIGS. 1 and 2 illustrate methods of manufacturing an organic photodetector (OPD) array 6 having a plurality of photodetector elements according to some embodiments.

In the embodiment of FIG. 1, the first and second electrodes are patterned. In the embodiment of FIG. 2, the first electrode 2 is unpatterned and the second electrode is patterned. In embodiments of both FIG. 1 and FIG. 2, the active area of each of the plurality of photodetector elements is defined by the overlap areas between the first and second electrodes.

The OPD comprises a substrate 1, a first electrode 2 supported on the substrate 1, a second electrode 4, a bulk heterojunction layer 3 comprising an organic electron acceptor and an organic electron donor between the first and second electrodes and an encapsulating layer 5 formed over the second electrode 4 and in direct contact with the bulk heterojunction layer where the encapsulating layer overlaps with the bulk heterojunction layer outside the second electrode areas.

A layer “between” and/or “disposed between” two other layers, as described herein, may be in direct contact with each of the two layers or may be between or may be spaced apart from one or both of the two other layers by one or more intervening layers. The first electrode may be an anode or a cathode, preferably an anode. The second electrode may be an anode or a cathode, preferably a cathode.

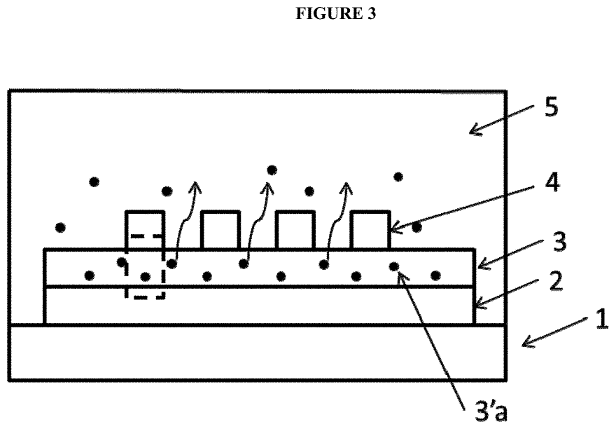

FIG. 3 shows a side of view of an OPD according to some embodiments wherein the OPD comprises a plurality of photodetector elements, for example as described with reference to FIGS. 1 and 2, and wherein the bulk heterojunction layer outside the plurality of active areas is in direct contact with encapsulation layer 5.

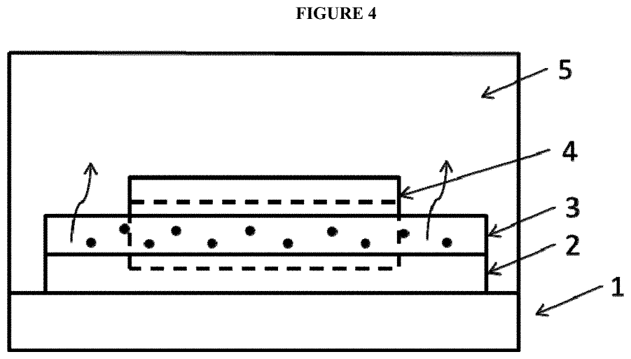

FIG. 4 shows a side view of an OPD according to some embodiments wherein the OPD has only one photodetector element and wherein the bulk heterojunction layer outside the active area of the photodetector element is in direct contact with an encapsulation layer 5.

One or more further layers may be provided between the anode and the cathode. A hole-transporting layer and/or a hole-injecting layer may be provided between the anode and the bulk heterojunction layer. An electron-transporting layer and/or an electron injecting layer may be provided between the cathode and the bulk heterojunction layer.

In some embodiments, as illustrated in FIGS. 1, 2 and 3, the second electrode is a discontinuous electrode comprising at least two discrete second electrode areas spaced apart from one another. A discontinuous electrode as described herein comprises a plurality of discrete electrode areas, e.g. the discrete electrode areas are spatially separated such that no electrode material of the discontinuous electrode extends between the two discrete areas.

Overlap areas between the first and second electrodes define active photodetector element areas of the bulk heterojunction layer, illustrated as a dashed area for one of the active areas in FIG. 3 and for the active area of FIG. 4.

In some embodiments, the bulk heterojunction layer is a continuous layer extending across the discrete second electrode areas and between the discrete second electrode areas.

The continuous layer may have any shape. The continuous layer extends in an unbroken line between any two points of the continuous layer.

According to some embodiments, for example as illustrated in FIGS. 1 and 2 the first electrode is a continuous layer.

According to some embodiments, the first electrode is a discontinuous electrode comprising at least two discrete first electrode areas spaced apart from one another.

In some embodiments, the OPD is an OPD array. An OPD array comprises a plurality of organic photodetector elements, each organic photodetector element of the OPD array having an active area defined by an overlap area of the first electrode and a discontinuous second electrode. It will be understood that the overlap does not require the first electrode and/or the second electrode to be in direct contact with the bulk heterojunction layer; one or more intervening layers may be present, as described herein.

According to some embodiments, the distance between any two active areas is less than 10 mm, optionally less than 5 mm.

The OPD comprises an encapsulation layer. The encapsulation layer is in direct contact with the bulk heterojunction layer. The encapsulation layer comprises an organic material, optionally a polymer.

According to some embodiments, the encapsulation layer may consist of a single material or the encapsulation layer may comprise a plurality of materials. The encapsulation layer may be an adhesive encapsulation layer containing the organic material. According to some embodiments, the encapsulation layer may comprise a PET, polyvinyl chloride and/or an acrylate or acrylic group containing compound. The encapsulation layer may contain a polymer which is formed following curing of an adhesive composition.

The encapsulation layer may be part of an encapsulant comprising one or more further encapsulation layers. The encapsulant may comprise a further encapsulation layer comprising or consisting of a metal, optionally aluminium. The aluminium may be aluminium foil.

The encapsulant may comprise a further encapsulation layer comprising or consisting of a polymer. The polymer may be polyethylene terephthalate.

The bulk heterojunction layer may comprise or consist of an organic electron acceptor and an organic electron donor.

The bulk heterojunction layer optionally has a thickness in the range of about 40-3000 nm, preferably 50-1000 nm or 50-500 nm.

The bulk heterojunction layer may be formed by any process including, without limitation, thermal evaporation and solution deposition methods.

Preferably, the bulk heterojunction layer is coated over the first electrode. Coating methods include those in which a formulation is indiscriminately deposited onto a surface.

Preferably, the bulk heterojunction layer is formed by depositing a formulation comprising the acceptor material and the electron donor material dissolved or dispersed in a solvent or a mixture of two or more solvents. The formulation may be deposited by any coating or printing method including, without limitation, spin-coating, dip-coating, roll-coating, spray coating, doctor blade coating, slit coating, dispense printing, ink jet printing, screen printing, gravure printing and flexographic printing.

In dispense printing a continuous flow of ink is deposited from a nozzle positioned at a defined distance from the substrate. A desired pattern may be created by a relative movement of the nozzle and the substrate.

By controlling the nozzle dispense rate (solution flow rate), the pattern density (line spacing), the nozzle movement speed (line speed) as well as the ink concentration, the uniformity of the bulk heterojunction layer film may be tuned.

The one or more solvents of the formulation may optionally comprise or consist of benzene substituted with one or more substituents selected from chlorine, C₁₋₁₀ alkyl and C₁₋₁₀ alkoxy wherein two or more substituents may be linked to form a ring which may be unsubstituted or substituted with one or more C₁₋₆ alkyl groups, optionally toluene, xylenes, trimethylbenzenes, tetramethylbenzenes, anisole, indane and its alkyl-substituted derivatives, and tetralin and its alkyl-substituted derivatives.

The formulation may comprise a mixture of two or more solvents, preferably a mixture comprising at least one benzene substituted with one or more substituents as described above and one or more further solvents. The one or more further solvents may be selected from esters, optionally alkyl or aryl esters of alkyl or aryl carboxylic acids, optionally a C₁₋₁₀ alkyl benzoate or benzyl benzoate.

The formulation may comprise further components in addition to the electron acceptor, the electron donor and the one or more solvents. As examples of such components, adhesive agents, defoaming agents, deaerators, viscosity enhancers, diluents, auxiliaries, flow improvers colourants, dyes or pigments, sensitizers, stabilizers, nanoparticles, surface-active compounds, lubricating agents, wetting agents, dispersing agents and inhibitors may be mentioned.

According to some embodiments, the method comprises heating the bulk heterojunction layer. With reference to FIG. 2b, heating of the bulk heterojunction layer may cause or facilitate the movement of a non-polymeric electron acceptor or electron donor 3′a to move towards a surface of the bulk heterojunction layer and into the encapsulation layer. It will be appreciated that the encapsulation layer is in contact with the second electrode, rather than in direct contact with the bulk heterojunction layer, in the active areas of the organic photodetector. The second electrode may prevent the non-polymeric electron acceptor or electron donor from moving out of the bulk heterojunction layer in the active areas.

The bulk heterojunction layer may undergo a phase separation under heating which causes one of the organic electron acceptor and organic electron donor to preferentially move into the encapsulation layer, thereby creating an electron donor and/or electron acceptor gradient across the thickness of the bulk heterojunction layer. Migration of the acceptor or donor into the encapsulation layer creates a lower concentration in the bulk heterojunction layer outside the active area or areas of one of a non-polymeric organic electron acceptor and a non-polymeric organic electron donor may lead to reduced lateral conductivity and higher resolution between organic photodetector elements of an organic photodetector array, or sharper edge resolution of a single photodetector or of organic photodetector elements at an edge of an organic photodetector array.

A difference in concentration of a non-polymeric electron acceptor and/or electron donor between active areas and non-active areas of a bulk heterojunction layer may be measured by time of flight secondary ion mass spectroscopy (ToF-SIMS) of the bulk heterojunction layer, and/or by measurement using this technique of increased concentration of a non-polymeric electron acceptor and/or electron donor in the encapsulation layer.

Heating of the bulk heterojunction layer is preferably at a temperature below 180° C., optionally at a temperature in the range of 60-150° C.

If an encapsulation layer is in contact with the bulk heterojunction layer outside a second electrode area then the electron donor or electron acceptor reaching the bulk heterojunction layer/encapsulation layer interface may be drawn into the encapsulation layer whereas an electron donor or electron acceptor reaching a bulk heterojunction layer/second electrode interface may be prevented by the second electrode from moving out of the bulk heterojunction layer.

In some embodiments, at least one of the organic electron acceptor and the organic electron donor is non-polymeric.

A non-polymeric compound as described herein may have a molecular weight of no more than 30,000 Daltons, optionally no more than 10,000 Daltons or no more than 5,000 Daltons.

The electron acceptor and the electron donor may each independently be a polymeric material or a non-polymeric material, provided that at least one of the organic electron acceptor and the organic electron donor is non-polymeric.

The electron donor material has a LUMO that is shallower than the LUMO of the electron acceptor material. Optionally, the gap between the LUMO acceptor and the LUMO donor is at least 0.1 eV. Optionally, the electron donor material has a LUMO of up to 3.5 eV from vacuum level, optionally 3.0-3.5 eV from vacuum level. Optionally, the electron donor material has a HOMO level of no more than 5.5 eV from vacuum level.

Optionally, the electron acceptor material has a LUMO level more than 3.5 eV from vacuum level, optionally 3.6-4.0 eV from vacuum level. Preferably, the LUMO of the electron acceptor is at least 1.2 eV, optionally at least 1.4 eV closer to vacuum than the work function of the anode.

HOMO and LUMO levels as described herein are as measured by square wave voltammetry.

It will be understood that the bulk heterojunction layer may contain a single electron donor material or a mixture of two or more electron donor materials, and the bulk heterojunction layer may contain a single electron acceptor material or a mixture of two or more electron acceptor materials.

Preferably, the electron donor is a polymer. Electron donor polymers are optionally selected from conjugated hydrocarbon or heterocyclic polymers including polyacene, polyaniline, polyazulene, polybenzofuran, polyfluorene, polyfuran, polyindenofluorene, polyindole, polyphenylene, polypyrazoline, polypyrene, polypyridazine, polypyridine, polytriarylamine, poly(phenylene vinylene), poly(3-substituted thiophene), poly(3,4-bisubstituted thiophene), polyselenophene, poly(3-substituted selenophene), poly(3,4-bisubstituted selenophene), poly(bisthiophene), poly(terthiophene), poly(bisselenophene), poly(terselenophene), polythieno[2,3-b]thiophene, polythieno[3,2-b]thiophene, polybenzothiophene, polybenzo[1,2-b:4,5-b′]dithiophene, polyisothianaphthene, poly(mono substituted pyrrole), poly(3,4-bisubstituted pyrrole), poly-1,3,4-oxadiazoles, polyisothianaphthene, derivatives and co-polymers thereof.

Preferred examples electron-donor polymers are copolymers of polyfluorenes and polythiophenes, each of which may be substituted, and polymers comprising benzothiadiazole-based and thiophene-based repeating units, each of which may be substituted. The electron donor preferably comprises a repeat unit of formula (I):

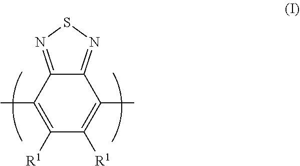

wherein R¹ in each occurrence is independently H or a substituent.

Optionally, each R¹ is independently selected from the group consisting of:

C₁₋₂₀ alkyl wherein one or more non-adjacent, non-terminal carbon atoms of the alkyl group may be replaced with O, S or C═O and wherein one or more H atoms of the C₁₋₂₀ alkyl may be replaced with F; an aryl or heteroaryl group, preferably phenyl, which may be unsubstituted or substituted with one or more substituents; and fluorine.

Substituents of an aryl or heteroaryl group are optionally selected from F, CN, NO₂ and C₁₋₂₀ alkyl wherein one or more non-adjacent, non-terminal carbon atoms of the alkyl group may be replaced with O, S or C═O.

By “non-terminal” as used herein is meant a carbon atom other than the methyl group of a linear alkyl (n-alkyl) chain and the methyl groups of a branched alkyl chain.

A polymer comprising a repeat unit of formula (I) is preferably a copolymer comprising one or more co-repeat units.

The one or more co-repeat units may comprise or consist of one or more of C₆₋₂₀ monocyclic or polycyclic arylene repeat units which may be unsubstituted or substituted with one or more substituents; 5-20 membered monocyclic or polycyclic heteroarylene repeat units which may be unsubstituted or substituted with one or more substituents.

The one or more co-repeat units may have formula (II):

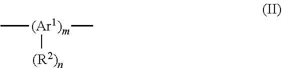

wherein Ar¹ in each occurrence is an arylene group or a heteroarylene group; m is at least 1; R² is a substituent; R² in each occurrence is independently a substituent; n is 0 or a positive integer; and two groups R² may be linked to form a ring.

Optionally, each R² is independently selected from the group consisting of a linear, branched or cyclic C₁₋₂₀ alkyl wherein one or more non-adjacent, non-terminal C atoms of the C₁₋₂₀ alkyl may be replaced with O, S, COO or CO.

Two groups R² may be linked to form a C₁₋₁₀ alkylene group wherein one or more non-adjacent C atoms of the alkylene group may be replaced with O, S, COO or CO.

Optionally, m is 2.

Optionally, each Ar¹ is independently a 5 or 6 membered heteroarylene group, optionally a heteroarylene group selected from the group consisting of thiophene, furan, selenophene, pyrrole, diazole, triazole, pyridine, diazine and triazine, preferably thiophene.

Optionally, the repeat unit of formula (II) has formula (IIa):

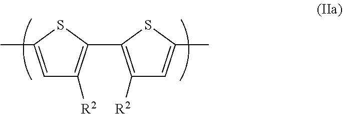

Optionally, the groups R² are linked to form a 2-5 membered bridging group. Optionally, the bridging group has formula —O—C(R¹⁶)₂— wherein R¹⁶ in each occurrence is independently H or a substituent. Substituents R¹⁶ are optionally selected from C₁₋₂₀ alkyl. Preferably each R¹⁶ is H.

An electron-accepting polymer, an electron-donating polymer or an anode polymer as described herein may have a polystyrene-equivalent number-average molecular weight (Mn) measured by gel permeation chromatography in the range of about 1×10³ to 1×10⁸, and preferably 1×10³ to 5×10⁶. The polystyrene-equivalent weight-average molecular weight (Mw) of the polymers described herein may be 1×10³ to 1×10⁸, and preferably 1×10⁴ to 1×10⁷.

Preferably, the electron acceptor is a non-polymeric compound.

In some embodiments, the electron acceptor is a non-fullerene acceptor. Exemplary non-fullerene acceptors include, without limitation, substituted or unsubstituted ITIC, IEICO, PDI or derivatives thereof, for example ITIC-2F, alkylated ITIC, ITIC-Th and IEICO-4F.

In some embodiments, the electron acceptor is a fullerene.

The fullerene may be a C₆₀, C₇₀, C₇₆, C₇₈ and C₈₄ fullerene or a derivative thereof including, without limitation, PCBM-type fullerene derivatives (including phenyl-C61-butyric acid methyl ester (C₆₀PCBM) and phenyl-C71-butyric acid methyl ester (C₇₀PCBM)), TCBM-type fullerene derivatives (e.g. tolyl-C61-butyric acid methyl ester (C₆₀TCBM)), and ThCBM-type fullerene derivatives (e.g. thienyl-C61-butyric acid methyl ester (C₆₀ThCBM)).

Fullerene derivatives may have formula (III):

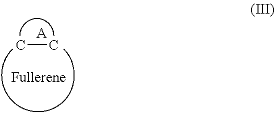

wherein A, together with the C—C group of the fullerene, forms a monocyclic or fused ring group which may be unsubstituted or substituted with one or more substituents.

Exemplary fullerene derivatives include formulae (IIIa), (IIIb) and (IIIc):

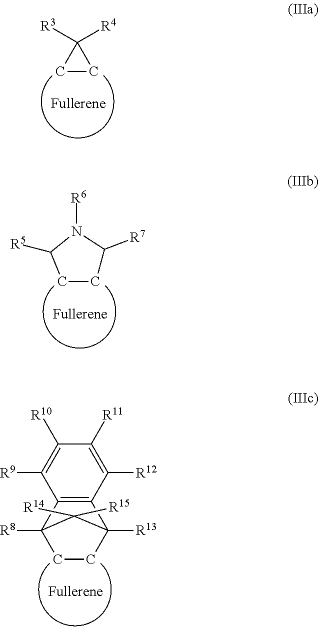

wherein R³-R¹⁵ are each independently H or a substituent.

Substituents R³-R¹⁵ are optionally and independently in each occurrence selected from the group consisting of aryl or heteroaryl, optionally phenyl, which may be unsubstituted or substituted with one or more substituents; and C₁₋₂₀ alkyl wherein one or more non-adjacent, non-terminal C atoms may be replaced with O, S, CO or COO and one or more H atoms may be replaced with F.

Substituents of aryl or heteroaryl, where present, are optionally selected from C₁₋₁₂ alkyl wherein one or more non-adjacent, non-terminal C atoms may be replaced with O, S, CO or COO and one or more H atoms may be replaced with F.

The first electrode and/or the second electrode may comprise at least one layer. The first electrode and/or second electrode may comprise or consists of a metal layer.

The first and/or second electrode may be deposited by any coating or printing method.

Preferably, the first electrode is coated over the substrate. Coating methods include those in which a formulation is indiscriminately deposited onto a surface.

Preferably, the second electrode is formed by a selective deposition in the second electrode areas over the bulk heterojunction layer.

In some embodiments, the second electrode is formed by a printing method in which a formulation is selectively applied to predetermined second electrode areas.

Preferably, the second electrode is formed in the second electrode areas by evaporation through a shadow mask.

Preferably, the cathode comprises or consists of a layer in direct contact with the bulk heterojunction layer.

The anode preferably comprises or consists of a material having a work function of at least 5.0 eV, preferably at least 5.1 eV, at least 5.2 eV or at least 5.3 eV. The anode may have a work function in the range of 5.0-6.0 eV.

The anode preferably consists of the material having a work function of at least 5.0 eV. If one or more further materials are present in the anode then the material having a work function of at least 5.0 eV preferably makes up at least 60 wt % of the anode.

The anode may comprise, without limitation, a metal for example gold; a conductive metal compound for example a conductive metal oxide such as molybdenum, or a conductive polymer. The anode preferably comprises ITO. The material may be a conductive polymer. Exemplary conductive polymers are fused or unfused polythiophenes, optionally poly(ethylenedioxythiophene) (PEDOT) having a charge-balancing polyanion, optionally polystyrene sulfonate (PSS). The anode may comprise, in addition to the conductive polymer, a charge-neutral derivative of the polyanion, for example a protonated polyacid or a salt thereof, such as polystyrene sulfonic acid (PSSH) or a salt thereof.

The anode may be deposited from an anode formulation comprising or consisting of the material or materials of the anode dissolved or dispersed in one or more liquid materials. Preferably, the only liquid material is water, or the liquid materials comprise water and one or more water-miscible liquid materials, optionally one or more protic or aprotic organic liquid materials, optionally DMSO. The anode formulation may comprise a surfactant. The surfactant may be a non-ionic or ionic surfactant. The surfactant may be a fluorinated surfactant.

Following deposition of the anode formulation, the anode layer may be heated. If the anode formulation is deposited over the bulk heterojunction layer then heating is preferably at a temperature below 150° C., optionally at a temperature in the range of 80-150° C.

The work function of the anode may be affected by factors including, without limitation: the anode material; constituents of an anode formulation other than the anode material, for example the liquids of the anode formulation and any additives present in the anode layer, for example any surfactants; the heating temperature of an anode layer.

If the anode formulation is deposited directly onto the bulk heterojunction layer then the materials of the bulk heterojunction layer preferably undergo little or no dissolution on contact with the liquid material or materials of the anode formulation. Optionally, the bulk heterojunction layer is deposited from a formulation comprising one or more non-polar solvents, optionally a substituted benzene as described in more detail below, and the anode is deposited onto the bulk heterojunction layer from an anode formulation.

At least one of the anode and cathode electrodes may be transparent so that light incident on the device may reach the bulk heterojunction layer. Preferably the anode is transparent.

The or each transparent electrode preferably has a transmittance of at least 70%, optionally at least 80%, to wavelengths in the range of 400-900 nm.

The device may be formed by forming the bulk heterojunction layer over one of the anode and cathode supported by a substrate and depositing the other of the anode or cathode over the bulk heterojunction layer.

The substrate may be, without limitation, a glass or plastic substrate. The substrate is transparent if, in use, incident light is to be transmitted through the substrate and the electrode supported by the substrate.

The substrate supporting one of the anode and cathode may or may not be transparent if, in use, incident light is to be transmitted through the other of the anode and cathode.

The cathode comprises at least one conducting layer. The or each conductive layer may comprise or consist of one or more metals, for example silver, aluminium, silver or Ag:Mg alloy, or a conductive metal oxide.

Optionally, the cathode comprises or consists of a layer of conductive metal oxide, optionally ITO, wherein a cathode modification layer is provided between the cathode and the bulk heterojunction layer.

According to some embodiments the first electrode and the second electrode are connected to circuitry which may include a voltage source for applying a reverse bias to the device and a detector (e.g. Current meter or readout device, wired in series with the reverse bias voltage source, as detection circuit), for example, to measure the generated photocurrent. Conversion of light incident on the bulk heterojunction layer into electrical current may be detected in reverse bias mode.

The OPD as described herein may be used in a wide range of applications including, without limitation, detecting the presence and/or brightness of ambient light and in a sensor comprising the organic photodetector and a light source. The OPD may be configured such that light emitted from the light source is incident on the photodetectors and changes in wavelength and/or brightness of the light may be detected. The sensor may be, without limitation, a gas sensor, a biosensor, an X-ray imaging device, a motion sensor (for example for use in security applications) a proximity sensor or a fingerprint sensor.

### EXAMPLE 1

A conducting polymer (from Nissan Chemical Laboratories) was deposited by inkjet printing onto ITO supported on a glass substrate to form a hole injection layer. A composition of a conjugated donor polymer as disclosed in WO2011/052709and fullerene acceptor C70 PCBM 1:2 w/w was applied by inkjet printing onto the hole injection layer to form a bulk heterojunction layer. A silver cathode was formed over the bulk heterojunction layer in 3 parallel tracks to form an organic photodetector. An encapsulant layer comprising a flexible adhesive (Tesa 61500) was formed over the cathode and the exposed underlying bulk heterojunction layer. A layer of aluminium foil and a layer of polyethylene terephthalate were provided over the adhesive layer. The organic photodetector was placed in an oven at 80° C. for 1 hour.

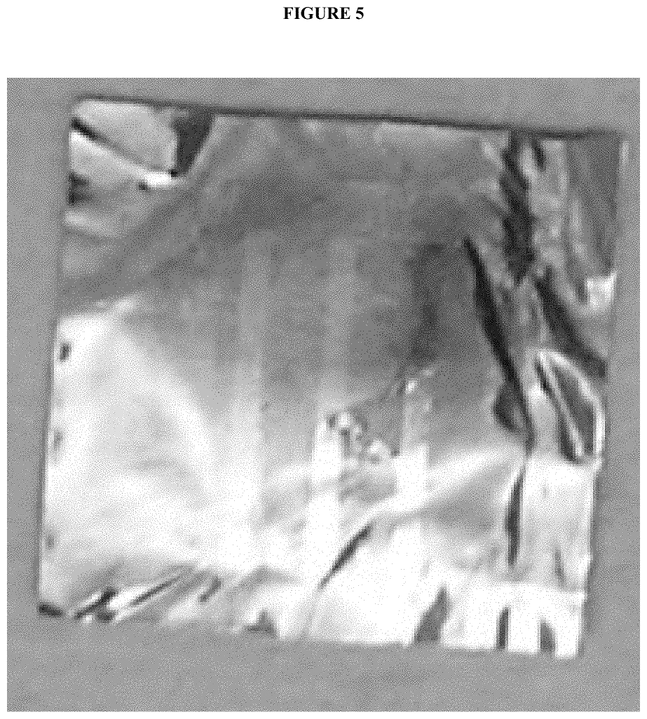

Following heating, the aluminium foil was delaminated from the adhesive layer. With reference to FIG. 5, discoloration of the foil surface in contact with the adhesive layer was observed except in areas covered by the parallel cathode tracks, indicating that fullerene had migrated out of the bulk heterojunction layer except in the active areas where the cathode, rather than the bulk heterojunction layer, is in contact with the adhesive layer. A change in fullerene content outside the active areas before and after heating of the bulk heterojunction layer was confirmed by microscopy.

1. A method of manufacturing an organic photodetector, wherein the organic photodetector comprises a substrate, a first electrode supported on the substrate, a second electrode, a bulk heterojunction layer comprising an organic electron acceptor and an organic electron donor between the first and second electrodes, and an encapsulation layer comprising an organic material in direct contact with the bulk heterojunction layer wherein:
the organic photodetector has an active area defined by an overlap area of the first and second electrodes;
the bulk heterojunction layer has an area extending across the active area and outside the active area;
at least one of the organic electron acceptor and the organic electron donor is non-polymeric; and
the method comprises heating the bulk heterojunction layer.

2. A method according to claim 1, wherein:
the second electrode is a discontinuous electrode comprising a plurality of discrete second electrode areas spaced apart from one another defining, with the first electrode, a plurality of active areas; and
the bulk heterojunction layer is a continuous layer extending across the discrete second electrode areas and between the discrete second electrode areas.

3. The method according to claim 1, wherein the organic electron acceptor is a fullerene or a derivative thereof.

4. The method according to claim 4, wherein the organic electron acceptor is a fullerene derivative of formula (III): 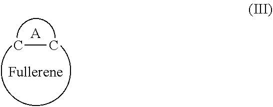
wherein A, together with the C—C group of the fullerene, forms a monocyclic or fused ring group which may be unsubstituted or substituted with one or more substituents.

5. The method according to claim 5, wherein the fullerene derivative of formula (III) is selected from formulae (IIIa), (IIIb) and (IIIc): 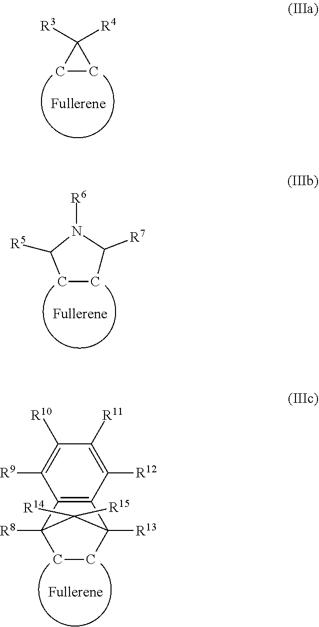
wherein R³-R¹⁵ are each independently H or a substituent.

6. The method according to claim 1, wherein the organic electron donor is a polymer.

7. The method according to according to claim 6, wherein the organic electron donor is a conjugated polymer.

8. The method according to claim 7, wherein the polymer comprises a repeat unit of formula (I): 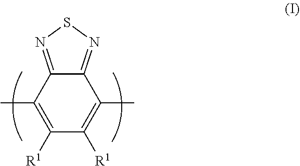
wherein R¹ in each occurrence is independently H or a substituent.

9. The method according to claim 1, wherein the first electrode and/or the second electrode comprises at least one layer comprising or consisting of a metal.

10. The method according to claim 1, wherein the distance between any two active areas is less than 10 mm.

11. The method according to claim 1, wherein the bulk heterojunction layer is formed over the first electrode by a coating method.

12. The method according to claim 2, wherein the second electrode is formed by a selective deposition method in each second electrode area.

13. The method according to claim 1, wherein the bulk heterojunction layer heating temperature is in the range of 60-150° C.

14. The method according to claim 1 wherein the organic material of the encapsulation is layer is a polymer.

15. An organic photodetector manufactured according the method of claim 1.

16. An organic photodetector according to claim 15, wherein the concentration of at least one of the organic electron donor and the organic electron acceptor in the bulk heterojunction layer is lower in an area outside of an active area than in an active area.

17. An organic photodetector comprising a substrate, a first electrode supported on the substrate, a second electrode, a bulk heterojunction layer comprising an organic electron acceptor and an organic electron donor between the first and second electrodes and an encapsulation layer comprising an organic material in direct contact with the bulk heterojunction layer, wherein:
the organic photodetector has an active area defined by an overlap area of the first and second electrodes;
the bulk heterojunction layer extends across the active area and outside of the active area;
at least one of the organic electron acceptor and the organic electron donor is a non-polymeric material; and
the concentration of at least one of the non-polymeric materials in the bulk heterojunction layer is lower in an area outside of the active area than in the active area.

18. The organic photodetector according to claim 17, wherein:
the second electrode is a discontinuous electrode comprising at least two discrete second electrode areas spaced apart from one another; and
the bulk heterojunction layer is a continuous layer extending across the discrete second electrode areas and between the discrete second electrode areas.

19. The organic photodetector according to claim 17 wherein the organic material of the encapsulation layer is a polymer.

20. A sensor comprising the organic photodetector of claim 17 and a light source.
